(19) United States
(12) Patent Application Publication
(10) Pub. No.: US 2023/0344194 A1
(43) Pub. Date: Oct. 26, 2023

(54) LASER LIGHT SOURCE AND METHOD OF MANUFACTURING THE SAME

(71) Applicant: NICHIA CORPORATION, Anan-shi (JP)

(72) Inventor: Hidenori MATSUO, Hadano-shi (JP)

(73) Assignee: NICHIA CORPORATION, Anan-shi (JP)

(21) Appl. No.: 18/304,103

(22) Filed: Apr. 20, 2023

(30) Foreign Application Priority Data
Apr. 25, 2022 (JP) 2022-071262

(51) Int. Cl. H01S 5/02325; H01S 5/40; H01S 5/02257; H01S 5/00; H01S 5/02253; H01S 5/02355; H01S 5/02255

(52) U.S. Cl. CPC H01S 5/02325; H01S 5/4093; H01S 5/02257; H01S 5/0014; H01S 5/4031; H01S 5/02253; H01S 5/02355; H01S 5/02255

(57) ABSTRACT

A laser light source includes: a substrate having an upper face and a lower face; one or more semiconductor laser devices configured to emit laser light, the one or more semiconductor laser devices being supported by the upper face of the substrate; a plurality of optical members configured to reflect or transmit the laser light; a supporting member secured to the substrate, the supporting member supporting at least one of the plurality of optical members; and a bonding layer located between the at least one of the plurality of optical members and the supporting member, the bonding layer bonding together the at least one of the plurality of optical members and the supporting member. A thermal conductivity of the supporting member is lower than that of the substrate.

### BACKGROUND

### Cross-Reference to Related Application

This application claims priority to Japanese Patent Application No. 2022-071262 filed on Apr. 25, 2022, the entire contents of which are hereby incorporated by reference.

### BACKGROUND

The present disclosure relates to a laser light source that includes a plurality of optical members, and a method of manufacturing the same.

Techniques have been developed for allowing optical members to be bonded to a substrate on which semiconductor laser devices are mounted. Japanese Patent Publication No. 2002-314188 describes a device in which a semiconductor laser array and a converging lens are disposed on a heat sink. A hole is made in the heat sink, through which adhesive filling is performed. This hole extends through to the bottom face of the converging lens.

### SUMMARY

Certain embodiments of the present disclosure provide laser light sources and methods of manufacturing the same for facilitating alignment of optical members.

In one embodiment of the present disclosure, a laser light source includes: a substrate having an upper face and a lower face; one or more semiconductor laser devices configured to emit laser light, the one or more semiconductor laser devices being supported by the upper face of the substrate; a plurality of optical members configured to reflect or transmit the laser light; a supporting member secured to the substrate, the supporting member supporting at least one of the plurality of optical members; and a bonding layer located between the at least one of the plurality of optical members and the supporting member, the bonding layer bonding together the at least one of the plurality of optical members and the supporting member. The supporting member has a lower thermal conductivity than a thermal conductivity of the substrate.

In another embodiment of the present disclosure, a method of manufacturing a laser light source includes: providing one or more semiconductor laser devices configured to emit laser light; providing a plurality of optical members configured to reflect or transmit the laser light; providing a base that includes: a substrate having an upper face and a lower face; and a supporting member supporting at least one of the plurality of optical members and being secured to the substrate, the supporting member having a lower thermal conductivity than a thermal conductivity of the substrate; placing at least one of the plurality of optical members onto the supporting member via an uncured bonding member; and heating and curing the uncured bonding member to form a bonding layer from the cured bonding member.

With laser light sources and methods of manufacturing the same according to certain embodiments of the present disclosure, alignment of optical members is facilitated.

### BRIEF DESCRIPTION OF THE DRAWINGS

FIG. 1 is a perspective view of a laser light source according to a first embodiment of the present disclosure.

FIG. 2 is a cross-sectional view of the laser light source in FIG. 1 taken along cross-sectional line II-II.

FIG. 3 is a perspective view of the laser light source according to the first embodiment, from which a cap is separated.

FIG. 4 is a top view of the laser light source according to the first embodiment, from which the cap is omitted.

FIG. 5 is a cross-sectional view of a base according to the first embodiment.

FIG. 6 is a bottom view showing a rear face of the base according to the first embodiment.

FIG. 7 is a cross-sectional view showing a substrate having supporting members placed thereon, in the first embodiment.

FIG. 8 is a cross-sectional view showing the substrate with optical members bonded onto the supporting members provided on the substrate, in the first embodiment.

FIG. 9 is a perspective view schematically showing a state before optical members are bonded to supporting members in the first embodiment.

FIG. 10 is a perspective view schematically showing a state before optical members are bonded to the substrate and a supporting member in a second embodiment of the present disclosure.

FIG. 11 is a perspective view schematically showing a state before optical members are bonded to one supporting member in a third embodiment of the present disclosure.

FIG. 12 is a perspective view schematically showing a state where two different kinds of optical members are respectively bonded onto two supporting members in a fourth embodiment of the present disclosure.

FIG. 13 is a cross-sectional view schematically showing a modified example of the laser light source according to the fourth embodiment.

FIG. 14A is a cross-sectional view schematically showing an exemplary configuration for a supporting member that may be adopted for each embodiment.

FIG. 14B is a cross-sectional view schematically showing another exemplary configuration for a supporting member that may be adopted for each embodiment.

FIG. 14C is a cross-sectional view schematically showing still another exemplary configuration for a supporting member that may be adopted for each embodiment.

FIG. 14D is a cross-sectional view schematically showing still another exemplary configuration for a supporting member that may be adopted for each embodiment.

### DETAILED DESCRIPTION

In the present specification and in the claims, polygons such as triangles and quadrangles are not limited to polygons in the strict mathematical sense, but shall also include shapes in which a corner(s) of the polygon is/are rounded, beveled, chamfered, filleted, or otherwise modified. Not only in the case of corners (ends of a side(s)) of the polygon, but also in the case in which a middle portion of a side(s) of the polygon is modified, the resulting shape shall also be referred to as a polygon. In other words, any shape that is partially modified while retaining the polygon as a base shall fall within the meaning of a “polygon” as described in the present specification and in the claims.

The same is true not only for polygons, but also for trapezoids, circles, concavities and convexities, and any other specific shape. The same is also true when referring to each side that forms the shape. In other words, even if a corner(s) or the middle portion of a side has been modified, the “side” is inclusive also of the modified portion(s). To distinguish a “polygon” or “side” that is not even locally modified from a modified version thereof, the word “strict” shall be applied, e.g., a “strict quadrangle.”

In the present specification and in the claims, where there are a plurality of elements identified by a certain name and each element is to be expressed distinctly, each of the elements may be prefixed with “first,” “second,” and other ordinal numerals. For example, while a claim recites that “semiconductor laser devices are arranged on a substrate,” it may be stated in the specification that “the first semiconductor laser device and the second semiconductor laser device are arranged on the substrate.” The ordinal numerals “first” and “second” are merely used in order to distinguish between the two semiconductor laser devices. There is no special meaning attached to the order of these ordinal numerals. In some cases, the names of elements with the same ordinal numeral may actually refer to different elements between the specification and the claims. For example, if the specification describes elements identified by the terms “first semiconductor laser device,” “second semiconductor laser device,” “third semiconductor laser device,” and so on, what is described as the “first semiconductor laser device” and the “second semiconductor laser device” in the claims may actually correspond to the “first semiconductor laser device” and the “third semiconductor laser device” in the specification. In the case in which the term “first semiconductor laser device” is used but the term “second semiconductor laser device” does not appear in claim 1, the invention according to claim 1 only needs to have one semiconductor laser device, such that this one light emitting element is not limited to the “first semiconductor laser device,” but can be the “second semiconductor laser device” or the “third semiconductor laser device” as used in the specification.

In the present specification and in the claims, terms indicating specific directions or positions (e.g., “upper/above/over,” “lower/below/under,” “right,” “left,” “front,” and “rear,” or any other terms of which these are parts) may be used. These terms are merely being used to indicate relative directions or positions in the drawing at issue, in a manner that provides easy understanding. So long as the relative directions or positions as indicated by terms such as “upper/above/over,” “lower/below/under,” etc., in the drawing at issue are conserved, any drawing employed outside the present disclosure, actually manufactured products, production apparatuses, or the like may not adhere to the same exact positioning as that indicated in the drawing at issue.

Note that the dimensions, dimensional ratio, shapes, interspace of arrangement, etc. of any component elements shown in a drawing may be exaggerated for ease of understanding. In order to avoid excessive complexity of the drawings, certain elements may be omitted from illustration.

Hereinafter, with reference to the drawings, embodiments of the present invention will be described. Although the embodiments illustrate specific implementations of the technological concept of the present invention, the invention is not limited to the described embodiments. The numerical values, shapes, materials, steps, and the order of the steps shown in the description of the embodiments are only examples, and various modifications are possible so long as there is no technical contradiction. In the following description, elements identified by the same name or reference numerals are the same or the same type of elements, and redundant explanations of those elements may be omitted.

### First Embodiment

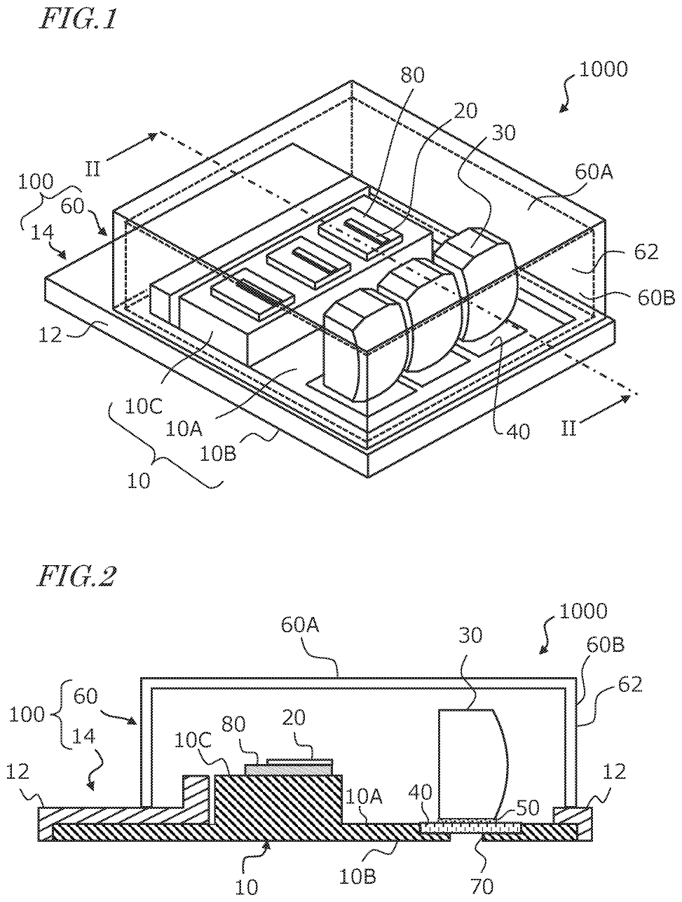

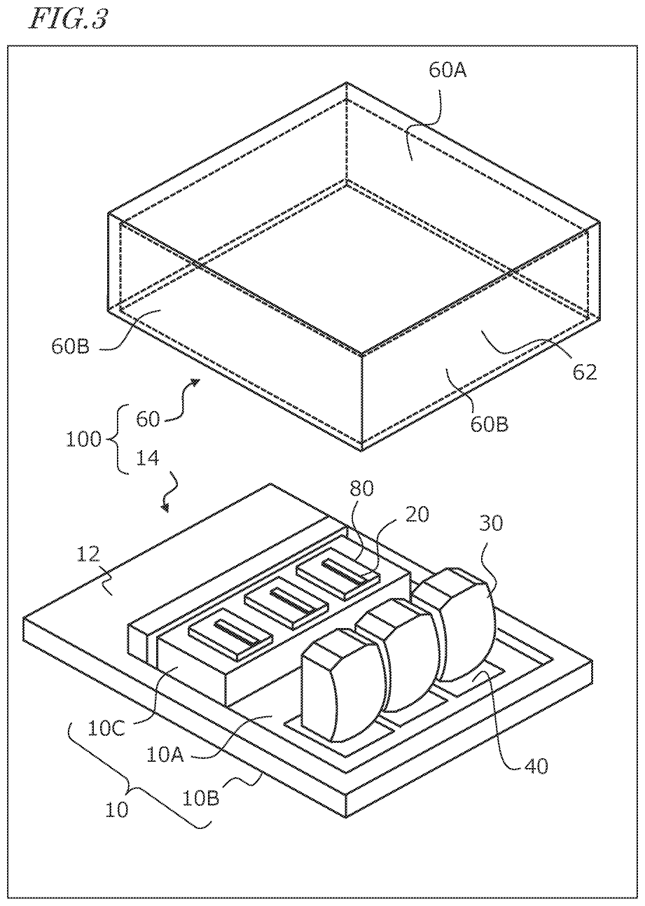

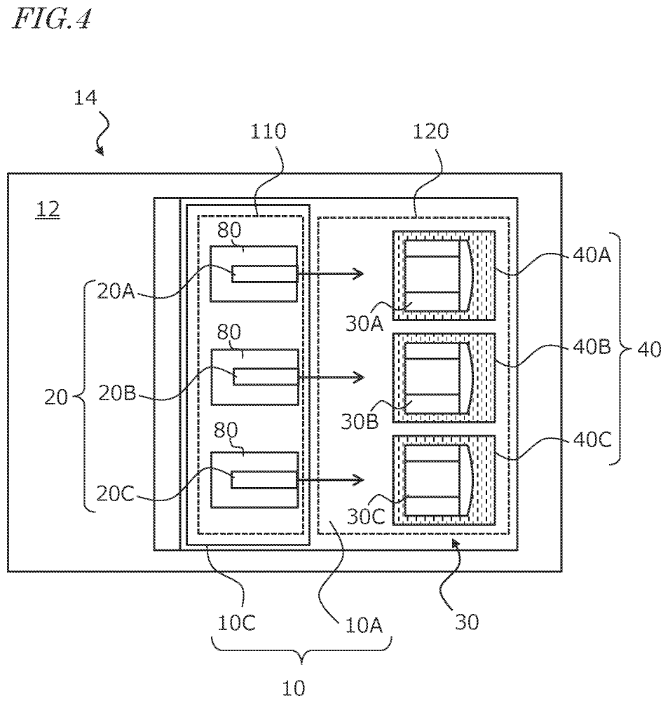

A laser light source 1000 according to a first embodiment will be described. FIG. 1 is a perspective view of the laser light source 1000 according to the first embodiment. FIG. 2 is a cross-sectional view of the laser light source 1000 taken along cross-sectional line II-II in FIG. 1. FIG. 3 is a perspective view of the laser light source 1000 according to the first embodiment, from which a cap 60 is separated.

The laser light source 1000 according to the present embodiment includes: a substrate 10 having an upper face 10A and a lower face 10B; and three semiconductor laser devices (laser diodes) 20 that are supported by the upper face 10A of the substrate 10. Each of the three semiconductor laser devices 20 emits laser light. In the illustrated example, each semiconductor laser device 20 is an edge-emitting type. Alternatively, each semiconductor laser device 20 may be a surface emitting type. The number of semiconductor laser devices 20 to be supported by the upper face 10A, of the substrate 10 is not limited to three, but may be one or two, or four or more.

In the present embodiment, lateral faces of substrate 10 are surrounded by a frame body 12. The frame body 12 may cover portions of the substrate 10 other than the lateral faces, e.g., a part of the upper face 10A. Hereinafter, the assemblage of the substrate 10 and the frame body 12 is referred to as a “base,” and denoted with the reference numeral “14.”

The laser light source 1000 includes: three optical members 30 to reflect or transmit laser light; and three supporting members 40 respectively supporting the three optical members 30. Examples of the optical members 30 are lenses, mirrors, beam splitters, or other optical parts. In the present embodiment, there are as many optical members 30 as there are semiconductor laser devices 20, such that each optical member 30 is at a position on which laser light emitted from the corresponding semiconductor laser device 20 is incident. Alternatively, as will be described later, laser light that is emitted from a single semiconductor laser device 20 may be transmitted or reflected by a plurality of optical members 30.

The supporting members 40 are secured to the substrate 10. As shown in FIG. 2, the laser light source 1000 includes a bonding layer 50 disposed between the optical members 30 and the supporting members 40, such that the optical members 30 and the supporting members 40 are bonded together by the bonding layer 50. The thermal conductivity of the supporting members 40 is lower than the thermal conductivity of the substrate 10. The function of the supporting members 40 will be described later.

The laser light source 1000 according to the first embodiment includes a cap 60 that covers the semiconductor laser devices 20 and the optical members 30. The cap 60 is secured to the base 14. More specifically, in the first embodiment, the cap 60 is bonded to the frame body 12, and the cap 60 is secured to the substrate 10 via the frame body 12. Alternatively, the cap 60 may be directly bonded to the substrate 10. The cap 60 includes a light-transmissive region 62 for allowing laser light that is reflected by the plurality of optical members 30 or laser light that is transmitted through the plurality of optical members 30 to pass through.

The cap 60 and the base 14 function as a package in which the semiconductor laser devices 20 and the plurality of optical members 30 are hermetically sealed. Hereinafter, the assemblage of the cap 60 and the base 14 will be referred to as “package,” and denoted with the reference numeral “100.”

Hereinafter, an exemplary configuration of each element of the laser light source 1000 will be described in more detail.

### Exemplary Configuration of Cap

As shown in FIG. 3, the package 100 in the present embodiment includes: the base 14, on which the semiconductor laser devices 20 and the optical members 30 are mounted; and the cap 60, which is bonded to the base 14. In the illustrated example, a lower end of the cap 60 is bonded to an upper face of the frame body 12 of the base 14. The package 100 is able to hermetically seal any devices or members (e.g., the semiconductor laser devices 20 and the optical members 30) that are disposed inside the package 100.

The cap 60 covers the semiconductor laser devices 20 and the optical members 30 on the substrate 10. In the illustrated example, the cap 60 includes a flat upper face section 60A and four lateral wall sections 60B. The schematic shape of the cap 60 is an open box that is placed upside down. In a top view, the upper face section 60A of the cap 60 is shaped as a rectangle, the four sides of the rectangle being respectively connected to the four lateral wall sections 60B. Each of the four lateral wall sections 60B is orthogonal to the upper face section 60A.

The lateral wall sections 60B of the cap 60 are located outside a region of the upper face 10A of the substrate 10 on which devices or members are disposed, and extend above the upper face 10A. Any device or member that may be disposed on the upper face 10A is surrounded by the lateral wall sections 60B. The upper face section 60A of the cap 60 is in a position opposite the upper face 10A, of the substrate 10, and is connected to upper ends of the lateral wall sections 60B.

In the laser light source 1000 according to the first embodiment, the light-transmissive region 62 of the cap 60 is located in one of the lateral wall sections 60B of the cap 60. Alternatively, the light-transmissive region 62 may be located in the upper face section 60A of the cap 60.

The surface at the light-emitting side of the light-transmissive region 62 of the cap 60 functions as a “light extraction surface.” In the present embodiment, the “light extraction surface” is one of the outer lateral faces of the lateral wall sections 60B of the cap 60. In the present embodiment, the light-transmissive region 62 is perpendicular to the upper face 10A,of the substrate 10. The light-transmissive region 62 may be inclined with respect to the upper face 10A.

The “light-transmissive region” is defined as a region having a transmittance of 80% or more with respect to laser light that is emitted from the semiconductor laser devices 20. The cap 60 does not need to be light-transmissive in portions other than the portion on which laser light emitted from the semiconductor laser devices 20 is incident. Specifically, any surface other than the surface functioning as the light extraction surface may be made of a material that is not light-transmissive.

The cap 60 can be produced from a light-transmissive material such as glass, plastic, or quartz, by using a processing technique such as molding or etching, for example. The cap 60 may be formed by first forming the upper face section 60A and the lateral wall sections 60B by using the same material or different materials, and then bonding them together. For example, the upper face section 60A may be made of monocrystalline or polycrystalline silicon, while the lateral wall sections 60B may, in part or whole, be made of glass.

The package 100 is not limited to the implementation in which the plate-shaped base 14 and the box-shaped cap 60 are combined. For example, the base 14 may be shaped as a box with an open upper face, while the cap 60 may be a plate-shaped covering member. In a top view, the outer shape of the package 100 does not need to be rectangular, but may be a non-quadrangular polygon, circle, etc., for example.

In the present embodiment, a submount 80 supporting each semiconductor laser device 20 is disposed in the sealed space inside the package 100. In this example, each semiconductor laser device 20 is supported by the upper face 10A of the substrate 10 via a member such as the submount 80. The submounts 80 are not essential elements. The semiconductor laser devices 20 may be bonded to the upper face 10A of the substrate 10. Thus, in certain embodiments of the present disclosure, one or more semiconductor laser devices 20 are supported by the upper face 10A of the substrate 10. In the sealed space inside the package 100, not only these devices but also protection elements, a temperature measurement element, and/or a plurality of interconnects may be disposed, for example. The package 100 has a plurality of electrically-conducting regions for achieving electrical connection between devices within the sealed space and external elements, such electrically-conducting regions being located inside the cap 60. The plurality of electrically-conducting regions may be electrically connected to wiring regions located outside the cap 60 through an interconnection pattern or vias provided inside the frame body 12, for example. The wiring regions may be connected to electrical terminals that are provided on an upper face, a lower face, or a lateral face of the frame body 12.

### Exemplary Configuration of Base

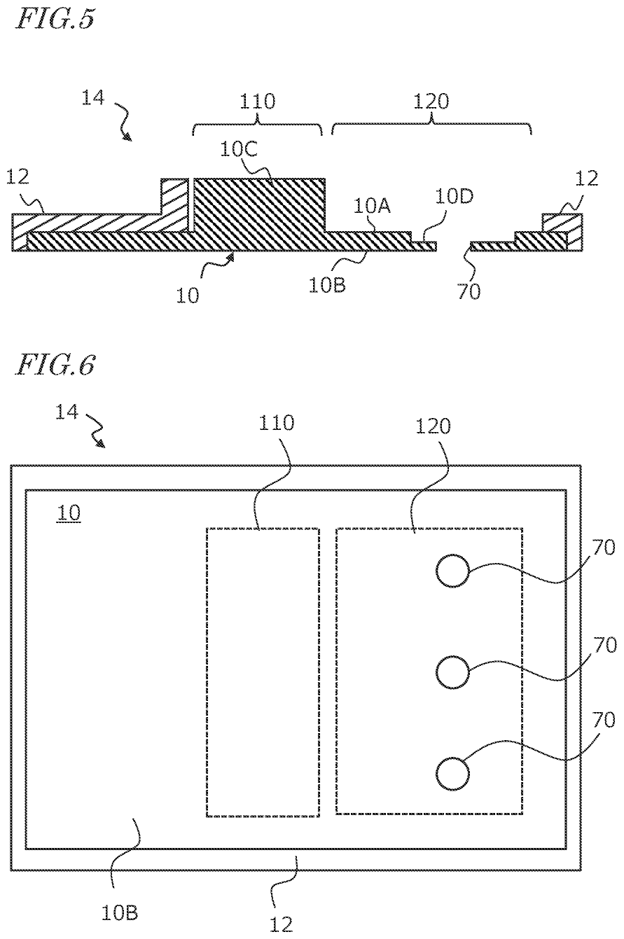

First, with reference to FIG. 4 to FIG. 6, an exemplary configuration of the base 14 will be described in detail. FIG. 4 is a top view of the laser light source 1000 according to the first embodiment, from which the cap 60 is omitted. FIG. 5 is a cross-sectional view of the base 14. FIG. 6 is a bottom view showing a rear face of the base 14.

The base 14 includes the substrate 10 and the frame body 12. The frame body 12 has a frame structure surrounding the lateral faces of the substrate 10, such that portions of the frame body 12 cover portions of the upper face 10A of the substrate 10. In the present embodiment, the upper face 10A of the substrate 10 includes: a first region 110, in which the semiconductor laser devices 20 are disposed; and a second region 120, in which the supporting members 40 are disposed. In the example shown in FIG. 4, three submounts 80 are provided in the first region 110, each submount 80 having one semiconductor laser device 20 placed thereon. Three supporting members 40 are provided in the second region 120, each supporting member 40 having one optical member 30 placed thereon.

The substrate 10 may be made of one or more materials selected from among: metals such as copper; diamond-based metal matrix composite materials; and graphite, for example. Such a substrate 10 has a thermal conductivity of e.g. 300 W/mK or more. On the other hand, the supporting members 40 are made of a material having a lower thermal conductivity than that of the substrate 10. A substrate 10 having good thermal conductivity functions to conduct the heat that is generated when the semiconductor laser devices 20 operates and release it to a heat dissipation device, e.g., a heat sink, that is in thermal contact with the lower face 103 of the substrate 10.

Example materials of the supporting members 40 include glass, ceramics, metals, and composite materials combining these materials. Such supporting members 40 may have a thermal conductivity of e.g. 0.5 to 1.1 W/mK, as in the case in which the material is a glass. The thermal conductivity of a supporting member 40 made of a ceramic may be e.g. 1.0 to 150 W/mK. In general, a highly-electrically insulative material has a low thermal conductivity, and therefore the supporting members 40 are preferably electrically insulative. However, so long as the supporting members 40 have a lower thermal conductivity than that of the substrate 10, a part or a whole of each supporting members 40 may be electrically conductive. For example, Kovar (which is electrically conductive) has a thermal conductivity of about 17 W/mK, which is relatively low among all metals. Because of the relatively low coefficient of thermal expansion of Kovar among all metals, using Kovar to form the supporting members 40 allows for reducing the difference between the coefficients of thermal expansion of the supporting members 40 and the optical members 30. Therefore, when the supporting members 40 are to be made from a metal, Kovar is preferably used as the metal. In a region of the upper face of each supporting member 40 where the optical member 30 is bonded, a layer of metal for enhancing bonding strength may be provided below the bonding layer 50.

The frame body 12 may be a member composed of a ceramic as its main material. Examples of ceramics to serve as the main material of the frame body 12 include aluminum nitride, silicon nitride, aluminum oxide, silicon carbide, and the like. The frame body 12 may include metal members, such as an interconnection pattern and/or vias. In the surface region of the frame body 12 to be bonded to the lower end of the cap 60, a metal film for bonding purposes may be provided. The material of the frame body 12 may be the same as or different from the material of the supporting members 40. From the standpoint of heat-releasing ability for releasing the heat generated by the semiconductor laser devices 20 to the outside, the frame body 12 preferably may have a higher thermal conductivity than that of the supporting members 40.

As shown in FIG. 5, the substrate 10 has a protrusion 10C that is located in the first region 110. Therefore, the relative height of the first region 110 of the upper face lop, with respect to the lower face 103 of the substrate 10 is higher than the relative height of the second region 120 of the upper face lop, with respect to the lower face 103 of the substrate 10. Moreover, the second region 120 of the upper face lop, of the substrate 10 has a recess 10D, in which at least a portion of each supporting member 40 is accommodated.

In the present embodiment, as shown in FIG. 4, the plurality of semiconductor laser devices 20 include a first semiconductor laser device 20A configured to emit first laser light, a second semiconductor laser device 20B configured to emit second laser light, and a third semiconductor laser device 20C configured to emit third laser light. Moreover, the plurality of optical members 30 include a first optical member 30A, configured to reflect or transmit first laser light, a second optical member 30B configured to reflect or transmit second laser light, and a third optical member 30C configured to reflect or transmit third laser light. The supporting members 40 include a first portion 40A supporting the first optical member 30A, a second portion 40B supporting the second optical member 30B, and a third portion 40C supporting the third optical member 30C. In the example of FIG. 4, the first portion 40A, the second portion 40B, and the third portion 40C are spaced apart from one another.

In FIG. 6, for ease of reference, the first region 110 and the second region 120 of the upper face lop, of the substrate 10 are indicated by broken lines. As a whole, the lower face 10B of the substrate 10 is flat for facilitating thermal contact with a heat sink or the like. The lower face of the frame body 12 exists around the lower face 10B of the substrate 10.

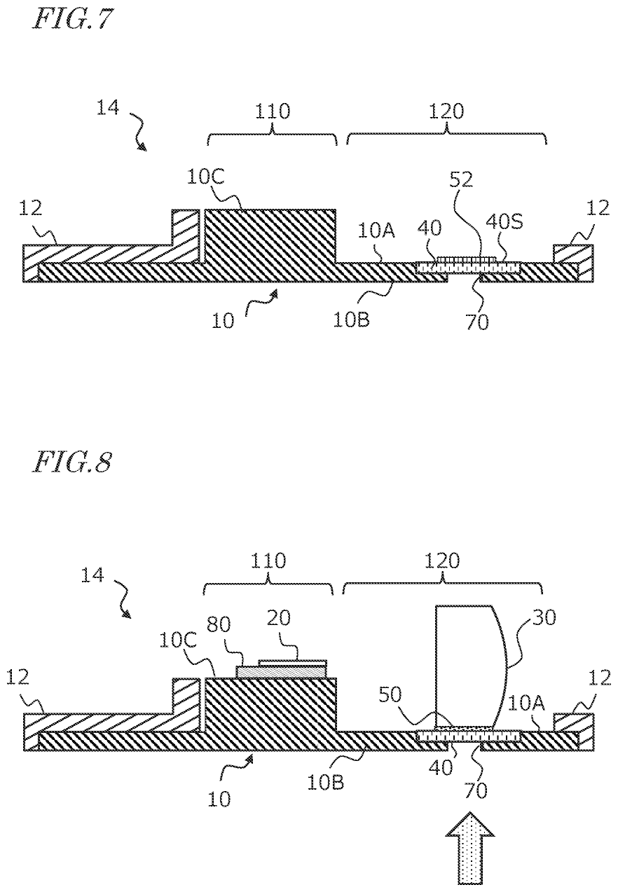

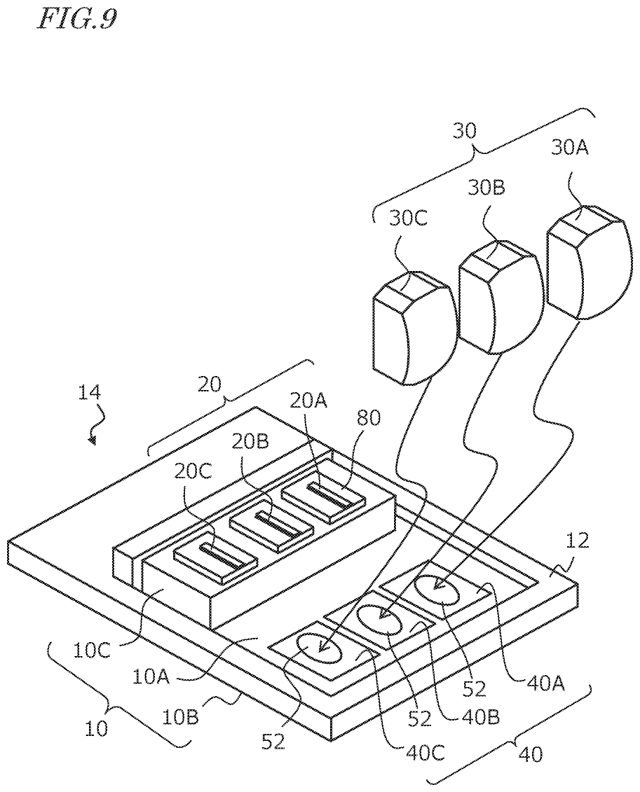

Hereinafter, with reference to FIG. 7 and FIG. 8, the functions of the protrusion 10C and the recess 10D of the substrate 10 will be described. FIG. 7 is a cross-sectional view showing the substrate 10 having the supporting members 40 placed thereon, and FIG. 8 is a cross-sectional view showing the substrate 10 with the optical members 30 bonded onto the supporting members 40. FIG. 8 also shows the submounts 80 (on which the semiconductor laser devices 20 are bonded) being bonded to the substrate 10.

As shown in FIG. 7, each supporting member 40 has a supporting surface 40S that is bonded to the optical member 30 via the bonding layer 50. An uncured bonding member 52 is provided on the supporting surface 40S. When irradiated with laser light for heating, the bonding member 52 is cured to become the bonding layer 50. In the example of FIG. 7, the second region 120 of the upper face 10A and the supporting surface 40S are on the same plane. In other words, the height of the supporting surface 40S with respect to the lower face 10B of the substrate 10 is equal to the height of the second region 120 of the upper face 10A with respect to the lower face 10B of the substrate 10. However, the relative height of the supporting surface 40S with respect to the lower face 10B of the substrate 10 may be greater or smaller than the relative height of the second region 120 of the upper face 10A with respect to the lower face 10B of the substrate 10. In the illustrated example, the supporting surface 40S of each supporting member 40 is flat. However, the supporting surface 40S does not need to be flat, so long as it has a shape that matches the shape of the lower face of each optical member 30.

As shown in FIG. 8, the protrusion 10C of the substrate 10 raises the position of the light-emitting end surface of each semiconductor laser device 20. This makes it easier for the height of the optical axis of laser light emitted from each semiconductor laser device 20 to be matched to the middle of the optical member 30 along the height direction. The height of the protrusion 10C, i.e., the relative height of the first region 110 of the upper face lop, with respect to the lower face 10B of the substrate 10, is determined according to the height of each optical member 30.

As shown in FIG. 8, the optical members 30 and the supporting members 40 are bonded together by the bonding layer 50. The bonding layer 50 is a member into which the bonding member 52 shown in FIG. 7 has been cured by being irradiated with laser light. The recess 10D located in the second region 120 of the upper face lop, of the substrate 10 accommodates at least a portion of each supporting member 40, thereby making it easier for the supporting member 40 to be secured to the substrate 10. The supporting members 40 are secured to the upper face lop, of the substrate 10 by using an adhesive or the like.

If the thickness of each supporting member 40 is greater than the depth of the recess 10D, the relative height of the supporting surface 40S of each supporting member 40 with respect to the lower face 10B of the substrate 10 increases. In order to obtain the aforementioned effect associated with an increased relative height of the first region 110 of the upper face 10A with respect to the lower face 10B of the substrate 10, the relative height of the supporting surface 40S of each supporting member 40 with respect to the lower face 10B of the substrate 10 is to be set lower than the relative height of the first region 110 of the upper face 10A with respect to the lower face 10B of the substrate 10.

However, the relative positioning between the semiconductor laser devices 20 and the optical members 30 is not limited to the illustrated example, and it is not essential to provide the protrusion 10C. In other words, it is not essential that the relative height of the first region 110 of the upper face 10A with respect to the lower face 10B of the substrate 10 be higher than the relative height of the second region 120 of the upper face 10A with respect to the lower face 10B of the substrate 10.

### Function of Supporting Member(s)

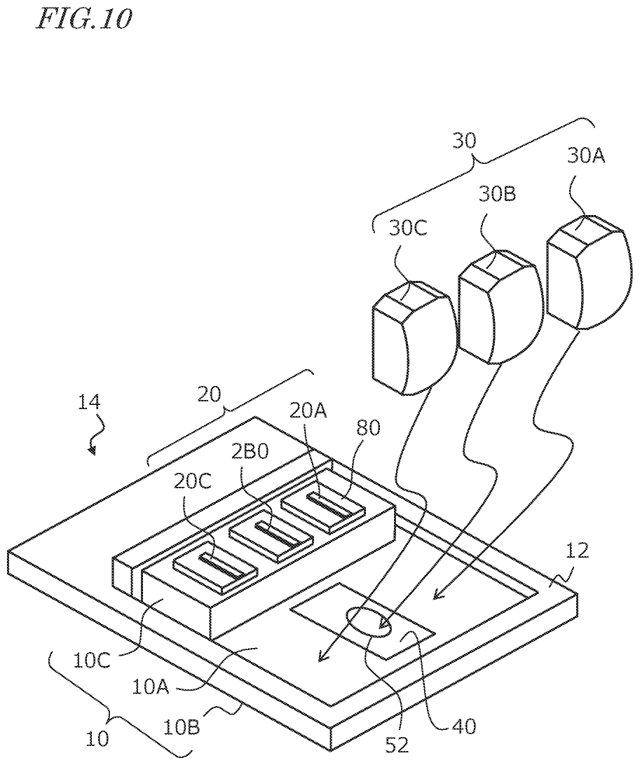

FIG. 9 is a perspective view schematically showing a state before an optical member 30 is bonded to each of the plurality of supporting members 40 in the present embodiment.

When bonding the plurality of optical members 30 to the supporting members 40, the bonding member 52 that is located between each optical member 30 and the corresponding supporting member 40 may be consecutively subjected to laser light irradiation in order to be heated, for example. When the bonding member 52 is cured to change into the bonding layer 50 through irradiation of such laser light for heating, the position and orientation of each optical member 30 become fixed with respect to the substrate 10. The position and orientation of each optical member 30 are adjusted in accordance with the direction of travel of the laser light that is emitted from the corresponding semiconductor laser device 20.

When one bonding member 52 is irradiated with laser light in order to cure that bonding member 52, the temperature of the supporting member 40 having that bonding member 52 placed thereon is increased. However, because the supporting member 40 has a lower thermal conductivity than that of the substrate 10, heat is unlikely to be conducted from the supporting member 40 having the increased temperature to its surroundings. This suppresses thermal interference on the uncured bonding member 52 associated with any other optical member 30 that is located in the surroundings. Even when a substrate 10 that is made of a material with high thermal conductivity (e.g., copper) is adopted, this enables “active alignment,” where curing of each bonding member 52 is performed while the position and orientation of each optical member 30 are accurately adjusted in accordance with the direction of travel of laser light that is emitted from the corresponding semiconductor laser device 20. In other words, alignment of the optical members 30 is facilitated according to the present embodiment. If the optical members 30 were to be directly bonded to a substrate 10 lacking such supporting members 40 by using bonding members 52, heat would be conducted, via the substrate 10 having high thermal conductivity, to other uncured bonding members 52 that have not been aligned. If such thermal interference occurs, the bonding members 52 associated with optical members 30 that have not yet been aligned may also become cured.

The bonding layer 50 in the present embodiment is a layer into which bonding members 52 of inorganic material have been cured, and may be made of an inorganic adhesive or a sintered metal. For example, a coating layer of metal particle paste that contains fine particles of metals such as gold, silver, or copper dispersed in a binder (bonding members 52) may be irradiated with laser light for heating, thereby sintering the fine particles to form the bonding layer 50. Irradiation of the laser light for heating will cause organic solvents, e.g., the binder, to volatilize. The bonding layer 50 might also be obtained by irradiating a thermosetting organic adhesive with laser light for heating and curing, for example. However, organic components might remain in the bonding layer that is made from an organic adhesive, and thus a gas of the organic components might occur inside the package 100 during operation of the laser light source 1000, unfavorably affecting the operation of the semiconductor laser devices 20. Therefore, the bonding layer 50 is preferably made of an inorganic adhesive or a sintered metal.

The substrate 10 in the present embodiment has at least one throughhole 70 that extends from the upper face 10A to the lower face 10B. The supporting members 40 close the throughhole(s) 70. When the lower face 10B of the substrate 10 is irradiated in the direction of a thick arrow shown in FIG. 8 with laser light for heating, the throughhole(s) 70 being provided immediately under the supporting members 40 will allow the laser light to go through the throughhole(s) 70 to reach the supporting members 40. Because the laser light is incident on the lower faces of the supporting members 40 so as to heat the supporting members 40, heating of the bonding members 52 can be achieved for curing. Thus, in the case in which the lower face of each supporting member 40 is irradiated with laser light through the throughhole(s) 70 in the substrate 10, there is an advantage in that any jigs and fixtures, etc., that are used for the alignment of the optical members 30 are unlikely to hinder the laser light irradiation.

The supporting members 40 in the present embodiment are made of a material that is not light-transmissive with respect to the laser light for heating. The supporting members 40 being made of a non-light-transmissive material absorb the incident laser light for heating and generate heat. This heat reaches the bonding members 52 to achieve a temperature increase and curing of the bonding members 52. The lower the thermal conductivity of the supporting members 40 is, the less likely it is for the heat generated in the portion irradiated by the laser light for heating to be dissipated to the surroundings, so that a local increase in temperature is more likely to occur at the portion irradiated by the laser light. When the lower faces of the supporting members 40 are irradiated with the laser light for heating, the thinner the supporting members 40 are, the easier it is to increase the temperature of the bonding members 52 located on the supporting surface 40S of the supporting members 40. The thickness of each supporting member 40 in this case may be e.g. 0.3 mm or less, and preferably 0.2 mm or less. However, if the supporting members 40 are too thin, the necessary rigidity (mechanical strength) for supporting the optical members 30 may not be attained. Therefore, the thickness of each supporting member 40 is 0.05 mm or more, and preferably 0.1 mm or more, for example. In the case in which the throughhole(s) 70 is not made in the substrate 10, the temperature increase and curing for the bonding members 52 can be achieved by irradiating the supporting surface 40S from above the supporting members 40 with the laser light for heating. In this case, the thickness of each supporting member 40 may exceed 0.3 mm.

Note that the supporting members 40 may be made of a light-transmissive material. As used herein, being “light-transmissive” refers to a transmittance of 80% or more with respect to the laser light for heating. In this case, too, the supporting members 40 made of a light-transmissive material will absorb a portion of the incident laser light for heating and generate heat. This heat will reach the bonding members 52 to achieve a temperature increase and curing of the bonding members 52. In addition, a portion of the laser light will be transmitted through the supporting members 40 and directly heat the bonding members 52.

The throughhole(s) 70 can not only be used as an aperture through which the laser light for heating is allowed to enter during the production process, but also be utilized during the operation of the laser light source 1000. For example, in the case in which the supporting members 40 are made of a light-transmissive material, it is possible to monitor a portion of the laser light that is emitted from a semiconductor laser device(s) 20 by utilizing the supporting members 40 and the throughhole(s) 70. Specifically, by providing a photodetection device at a position to receive a portion of the laser light that has been transmitted through a supporting member 40 and passed through the throughhole(s) 70, it is possible to monitor a portion of the laser light with a photodetection device.

### Exemplary Configuration of Semiconductor Laser Device

Each semiconductor laser device 20 may have a rectangular outer shape in a top view. In the case in which the semiconductor laser device 20 is an edge-emitting type semiconductor laser device, a lateral face that intersects one of the two shorter sides of the rectangle defines the light-emitting end surface. The semiconductor laser device 20 emits light from its light-emitting surface. In this example, an upper face and a lower face of the semiconductor laser device 20 each have a greater area than that of the light-emitting surface.

The semiconductor laser device 20 is a single-emitter device (i.e., having one emitter), for example. Note that the semiconductor laser device 20 may be a multi-emitter device (i.e., having two or more emitters). In the case in which the semiconductor laser device 20 is a semiconductor laser device having multiple emitters, one common electrode may be provided on one of the upper face and the lower face of the semiconductor laser device 20, and electrodes corresponding to the respective emitters may be provided on the other one of the upper face and the lower face.

The light that is emitted from the light-emitting surface of the semiconductor laser device 20 is divergent light having some spread. The light (laser light) that is emitted from the semiconductor laser device 20 creates a far field pattern (hereinafter referred to as “FFP”) of an elliptical shape at a face that is parallel to the light-emitting surface. An FFP refers to the shape, or optical intensity distribution, of outgoing light at a position away from the light-emitting surface.

Within a laser light beam, a ray of light that passes through the center of the elliptical shape of an FFP will be referred to as the optical axis of the laser light. Light traveling on the optical axis exhibits a peak intensity in the optical intensity distribution of the FFP. In the optical intensity distribution of an FFP, light having an intensity that is 1/e² or greater with respect to the peak intensity value may be referred to as the “main portion” of light.

In the elliptical shape of an FFP of light that is emitted from the semiconductor laser device 20, the minor axis direction of the ellipse will be referred to the “slow-axis direction,” and its major axis direction will be referred to as the “fast-axis direction.” The plurality of layers that compose the semiconductor laser device 20 (including an active layer) are layered in the fast-axis direction.

As the semiconductor laser device 20, for example, a semiconductor laser device emitting blue light, a semiconductor laser device emitting green light, a semiconductor laser device emitting red light, or the like may be adopted. Semiconductor laser devices emitting any other colors of light may also be adopted.

Herein, blue light refers to light that falls within an emission peak wavelength range from 420 nm to 494 nm. Green light refers to light that falls within an emission peak wavelength range from 495 nm to 570 nm. Red light refers to light that falls within an emission peak wavelength range from 605 nm to 750 nm.

Examples of semiconductor laser device emitting blue light or semiconductor laser devices emitting green light may be semiconductor laser devices containing a nitride semiconductor. As the nitride semiconductor, for example, GaN, InGaN, or AlGaN may be used. Examples of semiconductor laser devices emitting red light may be those containing an InAlGaP-based, GaInP-based, GaAs-based, or AlGaAs-based semiconductor.

### Exemplary Configuration of Submount

Each submount 80 has two bonding surfaces, and is shaped as a rectangular solid. At the opposite side to one bonding surface, the other bonding surface is provided. The distance between these two bonding surfaces is shorter than the distance between any other pair of two opposing surfaces. The shape of the submount 80 is not limited to a rectangular solid. The submount 80 may be made of aluminum nitride or silicon carbide. A metal film for bonding purposes is provided on the bonding surface.

### Exemplary Configuration of Optical Member

Examples of the optical members 30 include lens members, mirrors (reflective members), and beam splitters. A lens member has a lens surface, which may be configured to collimate incident light. The lens surface of a lens member converts light that diverges from the position of the focal point into collimated light through refraction. The lens surface may be spherical or aspherical. A lens surface(s) may be formed on the surface at the light-incident side of the lens member and/or the surface at the light-emitting side of the lens member. A concave lens surface may be formed on the light-incident side, and a convex lens surface may be formed on the light-emitting side of the lens member.

In the case in which each optical member 30 is a lens member, the optical member 30 may be made of a light-transmissive material, e.g., glass or plastic. In this case, although the portion of the optical member 30 through which light is not transmitted may have any arbitrary shape, it preferably has a shape that allows the optical member 30 to be secured to the supporting member 40.

In the case in which the optical member 30 is a reflective member, the optical member 30 may be made of a material that is light-reflective with respect to the surface on which the laser light is incident, e.g., a metal film, or a multilayer dielectric film. In this case, although the portion of the optical member 30 through which light is not transmitted may have any arbitrary shape, it preferably has a shape that allows the optical member 30 to be secured to the supporting member 40.

Each optical member 30 in the present embodiment has a flat lower face, for example, and this lower face may function as a bonding surface.

### Other Devices in Package

As described above, protection elements may be disposed in the sealed space inside the package 100. The protection elements are circuit elements to prevent semiconductor laser devices 20 from being destroyed by an excessive current flowing into it. A typical example of a protection element is a voltage regulating diode such as a Zener diode. As a Zener diode, an Si diode may be adopted. The temperature measurement element is a device used as a temperature sensor for measuring the surrounding temperature. As the temperature measurement element, a thermistor may be used, for example. Each interconnect is made of an electrical conductor having a linear shape, both ends of which serve as bonding sites. In other words, the interconnect has, at both ends of its linear body, bonding sites for bonding to other component elements. The interconnect may be a metal wire, for example. Examples of metals include gold, aluminum, silver, and copper.

### Second Embodiment

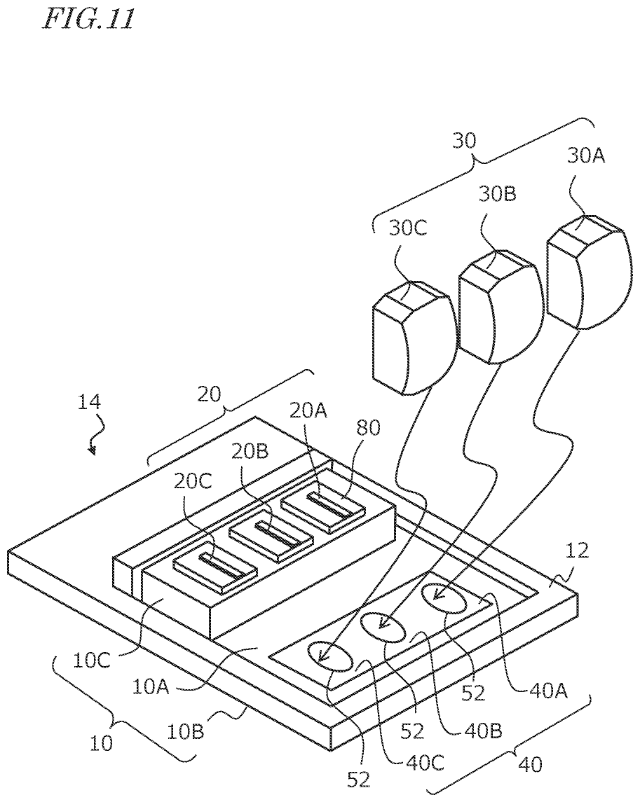

FIG. 10 is a perspective view schematically showing a state before optical members 30 are bonded to a substrate 10 and a supporting member 40 in a laser light source according to a second embodiment of the present disclosure. In the present embodiment, only the optical member 30 that is located in the middle among the three optical members 30 is bonded to the substrate 10 via the supporting member 40.

In the present embodiment, the plurality of semiconductor laser devices 20 include a first semiconductor laser device 20A to emit first laser light, a second semiconductor laser device 20B to emit second laser light, and a third semiconductor laser device 20C to emit third laser light. The plurality of optical members 30 include a first optical member 30A to reflect or transmit first laser light, a second optical member 30B to reflect or transmit second laser light, and a third optical member 30C to reflect or transmit third laser light. The second optical member 30B is located between the first optical member 30A and the third optical member 30C, and is supported by the supporting member 40. The first optical member 30A and the third optical member 30C are bonded to the upper face 10A of the substrate 10.

In the present embodiment, the irradiation of laser light for heating, which is performed in order to cure the bonding members 52, may be carried out so that the laser light is transmitted through the optical members 30, for example.

According to the present embodiment, one supporting member 40 that exists on the heat conduction path of the substrate 10 is able to hinder heat conduction during irradiation of laser light for heating. Therefore, similar effects to those described with reference to the first embodiment can be achieved. That is, even when a substrate 10 made of a material with high thermal conductivity (e.g., copper) is adopted, this enables “active alignment,” where curing of each bonding member 52 is performed while the position and orientation of each optical member 30 are accurately adjusted in accordance with the direction of travel of laser light that is emitted from the corresponding semiconductor laser device 20.

### Third Embodiment

FIG. 11 is a perspective view schematically showing a state before a plurality of optical members 30 are bonded to a substrate 10 and one supporting member 40 in a laser light source according to a third embodiment of the present disclosure.

In the present embodiment, the plurality of semiconductor laser devices 20 include a first semiconductor laser device 20A to emit first laser light, a second semiconductor laser device 20B to emit second laser light, and a third semiconductor laser device 20C to emit third laser light. The plurality of optical members 30 include a first optical member 30A to reflect or transmit first laser light, a second optical member 30B to reflect or transmit second laser light, and a third optical member 30C to reflect or transmit third laser light. The supporting member 40 includes a first portion 40A supporting the first optical member 30A, a second portion 40B supporting the second optical member 30B, and a third portion 40C supporting the third optical member 30C. The first portion 40A, the second portion 40B, and the third portion 40C are continuous. In other words, the first portion 40A, the second portion 40B, and the third portion 40C are not separate from one another.

In the present embodiment, too, the irradiation of laser light for heating, which is performed in order to cure the bonding members 52, may be carried out so that the laser light is transmitted through the optical members 30, for example. In the case in which a throughhole(s) is made that extends from the lower face 10B of the substrate 10 to the supporting member 40, the supporting member 40 may be irradiated with the laser light for heating through the throughhole(s).

According to the present embodiment, one supporting member 40 that exists on the heat conduction path of the substrate 10 is able to hinder heat conduction, whereby similar effects to those described with reference to the first and second embodiments can be achieved.

### Fourth Embodiment

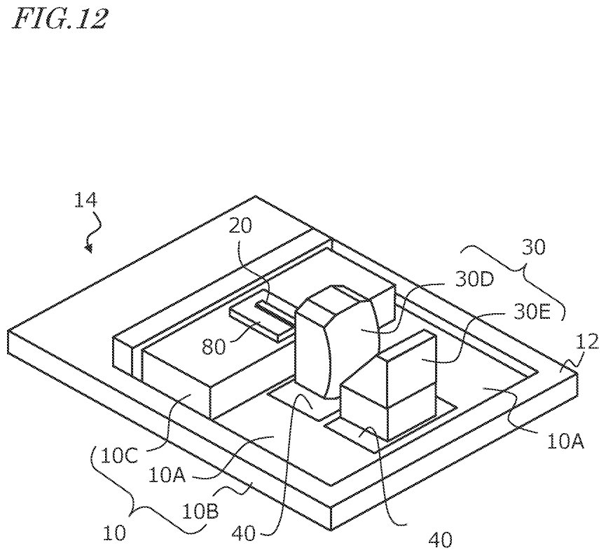

FIG. 12 is a perspective view schematically showing a state where two different kinds of optical members 30D and 30E are respectively bonded onto two supporting members 40 in a laser light source according to a fourth embodiment of the present disclosure.

In the present embodiment, one semiconductor laser device 20 is supported by the upper face 10A of the substrate 10, whereas a plurality of optical members 30 are provided to transmit or reflect laser light. The plurality of optical members 30 in this example include a first optical member 30D to function as a lens and a second optical member 30E to function as a mirror. Laser light that is transmitted and collimated through the first optical member 30D can be reflected upward by a reflective surface 30R of the second optical member 30E.

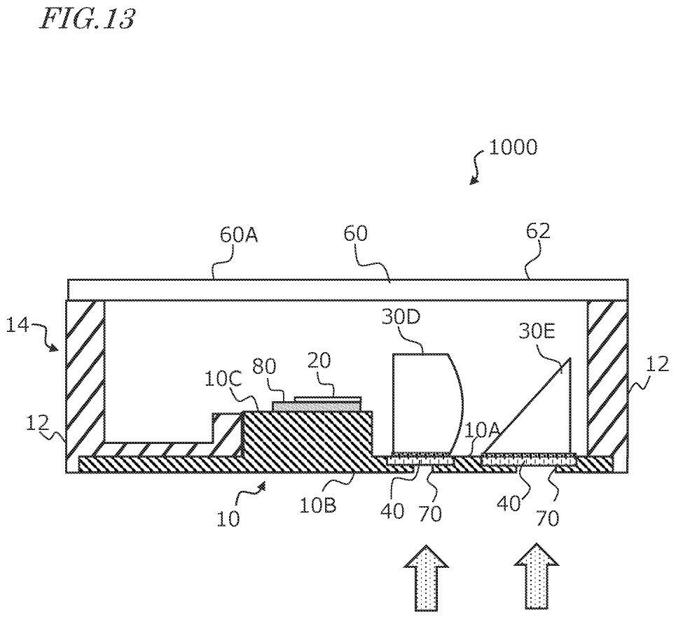

FIG. 13 is a cross-sectional view schematically showing a modified example of the laser light source 1000 according to the fourth embodiment. In this modified example, the frame body 12 includes lateral wall sections extending along the normal direction of the upper face 10A of the substrate 10. A plate-shaped cap 60 functions as a cover that is bonded to upper ends of the lateral wall sections of the frame body 12.

In this modified example, laser light that is reflected upward by the reflective surface 30R of the second optical member 30E is transmitted through the light-transmissive region 62 of the cap 60 and emitted upward. The configurations of the of the frame body 12 and the cap 60 in this modified example may also be adopted in each of the first to third embodiments. In that case, the second optical member 30E functioning as a mirror to reflect laser light upward may be provided; or, without providing the second optical member 30E, a light-transmissive region to transmit laser light may be provided in a portion of a lateral wall section(s) of the frame body 12.

The fourth embodiment illustrates an example where one semiconductor laser device 20 is provided on the substrate 10. However, a plurality of semiconductor laser devices 20 may be provided on the substrate 10. Each of the two optical members 30 (30D, 30E) shown in FIG. 12 may be allocated to each of such semiconductor laser devices 20.

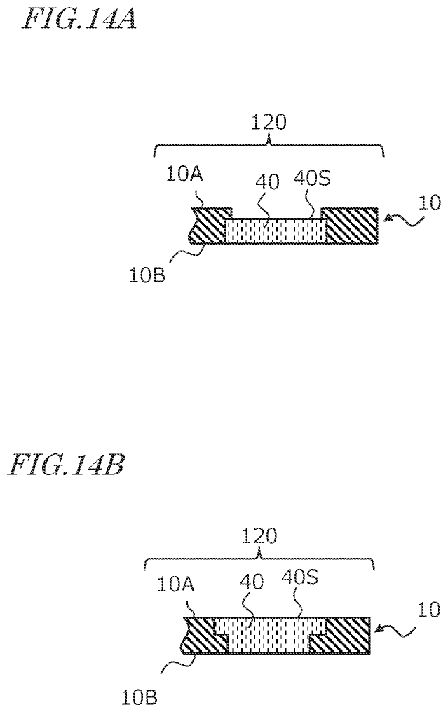

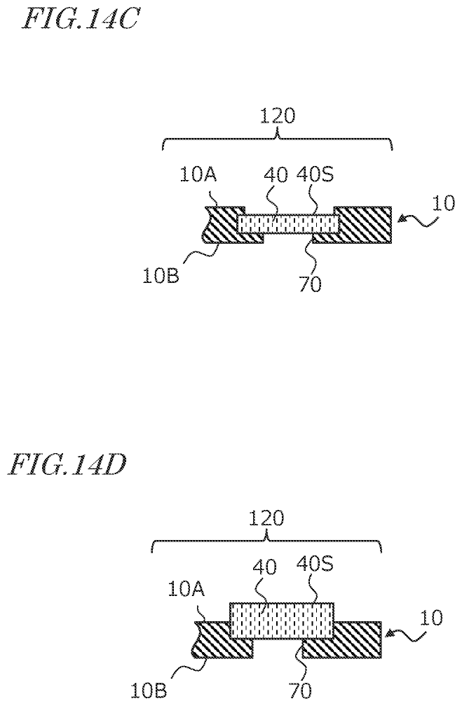

FIGS. 14A to 14D are cross-sectional view schematically each showing another exemplary configuration for a supporting member 40 that may be adopted for each of the above embodiments.

In the example of FIG. 14A, the relative height of the lower face of the supporting member 40 is equal to the relative height of the lower face 10B of the substrate 10. Moreover, the relative height of the supporting surface 40S with respect to the lower face 10B of the substrate 10 is lower than the relative height of the second region 120 of the upper face 10A with respect to the lower face 10B of the substrate 10. A step difference exists between the upper face 10A of the substrate 10 and the supporting surface 40S of the supporting member 40, thereby creating a recess. The supporting surface 40S corresponds to the bottom face of this recess. The bonding members 52 provided on the supporting surface 40S, i.e., the bottom face of the recess, are unlikely to protrude outside of the recess. Therefore, with the configuration of FIG. 14A, even if the optical members 30 are placed close together, interference of any one bonding member 52 protruding laterally to affect another adjacent optical member 30 is less likely.

In the example of FIG. 14B, the relative height of the lower face of the supporting member 40 is equal to the relative height of the lower face 10B of the substrate 10, and the relative height of the supporting surface 40S with respect to the lower face 10B of the substrate 10 is equal to the relative height of the second region 120 of the upper face 10A with respect to the lower face 10B of the substrate 10. An upper portion of the supporting member 40 has a laterally elongated shape as compared to its lower portion. In order to accommodate the supporting member 40 having this shape, an opening with a laterally elongated upper portion is made in the substrate 10, such that the supporting member 40 fits in this opening. With the configuration of FIG. 14B, the substrate 10 is able to firmly support the supporting member 40. In the configuration of FIG. 14B, the relative height of the supporting surface 40S with respect to the lower face 10B of the substrate 10 may be made lower than the relative height of the second region 120 of the upper face laA with respect to the lower face 10B of the substrate 10, thereby creating a recess. Alternatively, the lower face of the supporting member 40 may be made higher than the lower face 10B of the substrate 10. The supporting member 40, which has a lower thermal conductivity than that of the substrate 10, does not need to be in direct contact with a heat sink that is provided below. If the lower face of the supporting member 40 protrudes below the lower face 10B of the substrate 10 owing to manufacturing variations, placing the lower face 10B of the substrate 10 in contact with a heat sink may allow the supporting member 40 to interfere with the heat sink. Therefore, in order to account for the dimensional variations associated with manufacturing variations, it is preferable for the lower face of the supporting member 40 not to protrude below the lower face 10B of the substrate 10.

In the example of FIG. 14C, the relative height of the lower face of the supporting member 40 is higher than the relative height of the lower face 10B of the substrate 10, whereas the relative height of the supporting surface 40S with respect to the lower face 10B of the substrate 10 is lower than the relative height of the second region 120 of the upper face 10A with respect to the lower face 10B of the substrate 10. The substrate 10 does not need to have a single-layer structure, but may have a multilayer structure such that a plurality of layers are overlaid in a manner of sandwiching the supporting member 40 from above and below. With such a configuration, rather than the supporting member 40, the lower face 10B of the substrate 10 can be easily placed in good contact with a heat sink for an enhanced heat-releasing ability. Moreover, because the supporting surface 40S functions as the bottom face of a recess, similar effects to those described with reference to the configuration of FIG. 14A can be achieved.

In the example of FIG. 14D, the relative height of the lower face of the supporting member 40 is higher than the relative height of the lower face 10B of the substrate 10, and the relative height of the supporting surface 40S with respect to the lower face 10B of the substrate 10 is higher than the relative height of the second region 120 of the upper face 10A with respect to the lower face 10B of the substrate 10. With such a configuration, because the supporting surface 40S is at a higher position than the upper face 10A of the substrate 10, the size of the bottom face of the optical members 30 can be made larger than the size of the supporting surface 40S. Moreover, because the lower face of the supporting member 40 is at a higher position than the lower face 10B of the substrate 10, an effect of placing the lower face 10B of the substrate 10 in good contact with a heat sink can be achieved, as in the configuration of FIG. 14C.

### Manufacturing Method of Laser Light Source

The laser light source according to each embodiment of the present disclosure can be produced by a manufacturing method having the following steps, for example.

First, a step of providing one or more semiconductor laser devices 20 to emit laser light, a step of providing a plurality of optical members 30 to reflect or transmit laser light, and a step of providing a base 14 are performed (see FIG. 9 and the like). The base 14 includes: a substrate 10 having an upper face lop, and a lower face 10B; and a supporting member(s) 40 supporting at least one of the plurality of optical members 30. The supporting member(s) 40 is secured to the substrate 10, and has a lower thermal conductivity than that of the substrate 10.

Next, as shown in FIG. 9 to FIG. 11, a step of placing at least one of the plurality of optical members 30 onto the supporting member(s) 40 via an uncured bonding member(s) 52 is performed. Then, a step of heating to cure the bonding member(s) 52, thereby forming a bonding layer 50 from the bonding member(s) 52, is performed.

Although embodiments of the present invention have been described above, laser light sources according to the present invention are not to be limited to the laser light sources of the described embodiments. In other words, the present invention can be carried out without being limited to the outer shapes and structures of the laser light sources disclosed in the embodiments. For example, the laser light source may lack the protection elements. The present invention is applicable without requiring all of the component elements. For example, when a claim does not recite some of the component elements of a laser light source according to an embodiment, it is intended that such component elements permit design choices by one skilled in the art (e.g., replacement, omission, changes in shape, changes in material) and that the invention defined by the claim is still applicable.

The present disclosure provides exemplary laser light sources and manufacturing methods as recited in the following Items.

### [Item 1]

A laser light source comprising:
a substrate having an upper face and a lower face;
one or more semiconductor laser devices configured to emit laser light, the one or more semiconductor laser devices being supported by the upper face of the substrate;
a plurality of optical members configured to reflect or transmit the laser light;
a supporting member secured to the substrate, the supporting member supporting at least one of the plurality of optical members; and
a bonding layer located between the at least one of the plurality of optical members and the supporting member, the bonding layer bonding together the at least one of the plurality of optical members and the supporting member, wherein
the supporting member has a lower thermal conductivity than a thermal conductivity of the substrate.

### [Item 2]

The laser light source of Item 1, further comprising
a frame body surrounding lateral faces of the substrate; and
a cap covering the semiconductor laser device and the plurality of optical members and being secured to the substrate, wherein
the cap has a light-transmissive region for allowing the laser light having been reflected by the plurality of optical members or the laser light having been transmitted through the plurality of optical members to pass through.

### [Item 3]

The laser light source of Item 2, wherein the light-transmissive region of the cap is located on an upper face or a lateral face of the cap.

### [Item 4]

The laser light source of Item 2 or 3, wherein the cap, the frame body, and the substrate hermetically seal the semiconductor laser device and the plurality of optical members.

### [Item 5]

The laser light source of any one of Items 1 to 4, wherein,
the upper face of the substrate includes a first region in which the one or more semiconductor laser devices are disposed and a second region in which the supporting member is disposed; and
a relative height of the first region of the upper face with respect to the lower face of the substrate is higher than a relative height of the second region of the upper face with respect to the lower face of the substrate.

### [Item 6]

The laser light source of Item 5, wherein,
the supporting member has a supporting surface that is bonded to the at least one of the plurality of optical members via the bonding layer; and
a relative height of the supporting surface of the supporting member with respect to the lower face of the substrate is lower than the relative height of the first region of the upper face with respect to the lower face of the substrate.

### [Item 7]

The laser light source of Item 5 or 6, wherein the second region of the upper face of the substrate includes a recess, and at least a portion of the supporting member is accommodated in the recess.

### [Item 8]

The laser light source of any one of Items 1 to 7, wherein the bonding layer is made of an inorganic adhesive or a sintered metal.

### [Item 9]

The laser light source of any one of Items 1 to 8, wherein,
the substrate includes at least one throughhole that extends from the upper face to the lower face; and
the supporting member closes the at least one throughhole.

### [Item 10]

The laser light source of Item 9, wherein the supporting member is made of a light-transmissive material.

### [Item 11]

The laser light source of Item 10, further comprising a photodetection device provided at a position to receive a portion of the laser light having been transmitted through the supporting member and passed through the at least one throughhole in the substrate.

### [Item 12]

The laser light source of any one of Items 1 to 11, wherein,
the plurality of semiconductor laser devices include a first semiconductor laser device configured to emit first laser light, a second semiconductor laser device configured to emit second laser light, and a third semiconductor laser device configured to emit third laser light; and
the plurality of optical members include a first optical member configured to reflect or transmit the first laser light, a second optical member configured to reflect or transmit the second laser light, and a third optical member configured to reflect or transmit the third laser light.

### [Item 13]

The laser light source of Item 12, wherein,
the supporting member includes a first portion supporting the first optical member, a second portion supporting the second optical member, and a third portion supporting the third optical member; and
the first portion, the second portion, and the third portion are spaced apart from one another.

### [Item 14]

The laser light source of Item 12, wherein,
the supporting member includes a first portion supporting the first optical member, a second portion supporting the second optical member, and a third portion supporting the third optical member; and
the first portion, the second portion, and the third portion are continuous.

### [Item 15]

The laser light source of Item 12, wherein,
the second optical member is located between the first optical member and the third optical member, and supported by the supporting member; and
the first optical member and the third optical member are bonded to the upper face of the substrate.

### [Item 16]

A method of manufacturing a laser light source, the method comprising:
providing one or more semiconductor laser devices configured to emit laser light;
providing a plurality of optical members configured to reflect or transmit the laser light;
providing a base that includes: a substrate having an upper face and a lower face; and a supporting member supporting at least one of the plurality of optical members and being secured to the substrate, the supporting member having a lower thermal conductivity than a thermal conductivity of the substrate;
placing at least one of the plurality of optical members onto the supporting member via an uncured bonding member; and heating and curing the uncured bonding member to form a bonding layer from the cured bonding member.
laser light sources according to embodiments can be used for head-mounted displays, projectors, illuminations, processing, displays, and the like.

What is claimed is:

1. A laser light source comprising:
a substrate having an upper face and a lower face;
one or more semiconductor laser devices configured to emit laser light, the one or more semiconductor laser devices being supported by the upper face of the substrate;
a plurality of optical members configured to reflect or transmit the laser light;
a supporting member secured to the substrate, the supporting member supporting at least one of the plurality of optical members; and
a bonding layer located between the at least one of the plurality of optical members and the supporting member, the bonding layer bonding together the at least one of the plurality of optical members and the supporting member, wherein:
a thermal conductivity of the supporting member is lower than a thermal conductivity of the substrate.

2. The laser light source of claim 1, further comprising:
a frame body surrounding lateral faces of the substrate; and
a cap covering the semiconductor laser device and the plurality of optical members and being secured to the substrate, wherein:
the cap has a light-transmissive region configured to transmit the laser light that has been reflected by the plurality of optical members or transmitted through the plurality of optical members.

3. The laser light source of claim 2, wherein:
the light-transmissive region of the cap is located on an upper face or a lateral face of the cap.

4. The laser light source of claim 2, wherein:
the cap, the frame body, and the substrate hermetically seal the semiconductor laser device and the plurality of optical members.

5. The laser light source of claim 1, wherein:
the upper face of the substrate includes a first region in which the one or more semiconductor laser devices are disposed and a second region in which the supporting member is disposed; and
a relative height of the first region of the upper face with respect to the lower face of the substrate is higher than a relative height of the second region of the upper face with respect to the lower face of the substrate.

6. The laser light source of claim 5, wherein:
the supporting member has a supporting surface that is bonded to the at least one of the plurality of optical members via the bonding layer; and
a relative height of the supporting surface of the supporting member with respect to the lower face of the substrate is lower than the relative height of the first region of the upper face with respect to the lower face of the substrate.

7. The laser light source of claim 5, wherein:
the second region of the upper face of the substrate includes a recess, and at least a portion of the supporting member is accommodated in the recess.

8. The laser light source of claim 1, wherein:
the bonding layer is made of an inorganic adhesive or a sintered metal.

9. The laser light source of claim 1, wherein:
the substrate includes at least one throughhole that extends from the upper face to the lower face; and
the supporting member closes the at least one throughhole.

10. The laser light source of claim 9, wherein:
the supporting member is made of a light-transmissive material.

11. The laser light source of claim 10, further comprising:
a photodetection device located at a position to receive a portion of the laser light that has been transmitted through the supporting member and passed through the at least one throughhole in the substrate.

12. The laser light source of claim 1, wherein:
the plurality of semiconductor laser devices include a first semiconductor laser device configured to emit first laser light, a second semiconductor laser device configured to emit second laser light, and a third semiconductor laser device configured to emit third laser light; and
the plurality of optical members include a first optical member configured to reflect or transmit the first laser light, a second optical member configured to reflect or transmit the second laser light, and a third optical member configured to reflect or transmit the third laser light.

13. The laser light source of claim 12, wherein:
the supporting member includes a first portion supporting the first optical member, a second portion supporting the second optical member, and a third portion supporting the third optical member; and
the first portion, the second portion, and the third portion are spaced apart from one another.

14. The laser light source of claim 12, wherein:
the supporting member includes a first portion supporting the first optical member, a second portion supporting the second optical member, and a third portion supporting the third optical member; and
the first portion, the second portion, and the third portion are continuous.

15. The laser light source of claim 12, wherein:
the second optical member is located between the first optical member and the third optical member, and supported by the supporting member; and
the first optical member and the third optical member are bonded to the upper face of the substrate.

16. A method of manufacturing a laser light source, the method comprising:
providing one or more semiconductor laser devices configured to emit laser light;
providing a plurality of optical members configured to reflect or transmit the laser light;
providing a base that comprises:
a substrate having an upper face and a lower face, and
a supporting member supporting at least one of the plurality of optical members and being secured to the substrate, wherein a thermal conductivity of the supporting member is lower than a thermal conductivity of the substrate;
placing at least one of the plurality of optical members onto the supporting member via an uncured bonding member; and
heating and curing the uncured bonding member to form a bonding layer.
